(19) United States
(12) Patent Application Publication
(10) Pub. No.: US 2024/0397768 A1
(43) Pub. Date: Nov. 28, 2024

(54) Display Device

(71) Applicant: LG Display Co., Ltd., Seoul (KR)

(72) Inventors: Seung Jin Han, Paju-si (KR); Dhang Kwon, Paju-si (KR); Hang Sup Cho, Paju-si (KR)

(21) Appl. No.: 18/667,605

(22) Filed: May 17, 2024

(30) Foreign Application Priority Data
May 22, 2023 (KR) 10-2023-0065711

(51) Int. Cl. H10K 59/131; G09G 3/3266; G09G 3/3275

(52) U.S. Cl. CPC H10K 59/131; G09G 3/3266; G09G 3/3275; G09G 2330/021; G09G 2330/06

(57) ABSTRACT

Display devices are disclosed. The display device comprises a substrate including an electrostatic discharge area where an electrostatic discharge element is disposed and a normal area surrounding the electrostatic discharge area, a lower planarization layer disposed on the substrate, a first trench positioned between the electrostatic discharge area and the normal area, and disposed in the lower planarization layer, a first upper planarization layer positioned in the normal area, and disposed on the lower planarization layer, and an insulation layer disposed on the first upper planarization layer, the first trench, and the lower planarization layer, and formed of an inorganic material, thereby preventing electrolytic corrosion in the electrostatic discharge area.

### CROSS-REFERENCE TO RELATED APPLICATION

This application claims priority to Republic of Korea Patent Application No. 10-2023-0065711, filed in the Republic of Korea on May 22, 2023, which is hereby incorporated by reference in its entirety.

### BACKGROUND

### Field

Embodiments of the disclosure relate to a display device.

### Description of Related Art

The growth of the intelligent society leads to increased demand for various types of display devices. Representative examples of such display devices include liquid crystal devices (LCD) and organic light emitting display devices (OLED).

Organic light emitting display devices are mainly used as display devices with various shapes and functions due to various advantages, such as no need for a separate light source, capability of low-power driving and placement of variously shaped display areas on substrates in various shapes.

Various panel design techniques are being developed to reduce the bezel where no image is displayed or to downsize the display device, and one technique is to reduce the bezel through a bending structure.

Various signal lines pass through the bending area, and an electrostatic discharge element may be disposed adjacent to the bending area.

### SUMMARY

Embodiments of the disclosure may provide a display device that may prevent or at least reduce moisture or oxygen penetration into the electrostatic discharge area by introducing a trench structure and a double planarization layer in the planarization layer of the display device.

Embodiments of the disclosure may provide a display device that may prevent electrolytic corrosion in the electrostatic discharge area by introducing a trench structure and a double planarization layer in the planarization layer of the display device.

Embodiments of the disclosure may provide a display device capable of low power consumption by preventing electrolytic corrosion in the electrostatic discharge area to enhance the lifespan of the pixel.

Embodiments of the disclosure provide a display device comprising a substrate including an electrostatic discharge area where an electrostatic discharge element is disposed and a normal area surrounding the electrostatic discharge area, a lower planarization layer disposed on the substrate, a first trench positioned between the electrostatic discharge area and the normal area, and disposed in the lower planarization layer, a first upper planarization layer positioned in the normal area, and disposed on the lower planarization layer, and an insulation layer disposed on the first upper planarization layer, the first trench, and the lower planarization layer, and formed of an inorganic material.

Embodiments of the disclosure may provide a display device comprising a substrate including an electrostatic discharge area where an electrostatic discharge element is disposed and a normal area where the electrostatic discharge element is not disposed, a lower planarization layer disposed in the normal area and the electrostatic discharge area, and including an organic material, a first upper planarization layer positioned in the normal area, and disposed on the lower planarization layer, and an insulation layer disposed on the first upper planarization layer and the lower planarization layer, and formed of an inorganic material.

Embodiments of the disclosure may provide a display device that may prevent or at least reduce moisture or oxygen penetration into the electrostatic discharge area by introducing a trench structure and a double planarization layer in the planarization layer of the display device.

Embodiments of the disclosure may provide a display device that may prevent electrolytic corrosion in the electrostatic discharge area by introducing a trench structure and a double planarization layer in the planarization layer of the display device.

Embodiments of the disclosure may provide a display device capable of low power consumption by preventing or at least reducing electrolytic corrosion in the electrostatic discharge area to enhance the lifespan of the pixel.

### DESCRIPTION OF DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is an equivalent circuit diagram illustrating a subpixel in a display panel according to embodiments of the disclosure;

FIG. 3 is a view illustrating a display device according to embodiments of the disclosure;

FIG. 4 is an enlarged plan view illustrating the area 200 of FIG. 3 according to embodiments of the disclosure;

FIG. 5 is a cross-sectional view taken along line I-I′ of FIG. 4 according to embodiments of the disclosure;

FIG. 6 is another cross-sectional view taken along line I-I′ of FIG. 4 according to embodiments of the disclosure;

FIG. 7 is another enlarged plan view illustrating the area 200 of FIG. 3 according to embodiments of the disclosure;

FIG. 8 is a cross-sectional view taken along line II-II′ of FIG. 7 according to embodiments of the disclosure;

FIG. 9 is another cross-sectional view taken along line II-II′ of FIG. 7 according to embodiments of the disclosure; and

FIG. 10 is another cross-sectional view taken along line II-II′ of FIG. 7 according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, various embodiments of the disclosure are described in detail with reference to the accompanying drawings.

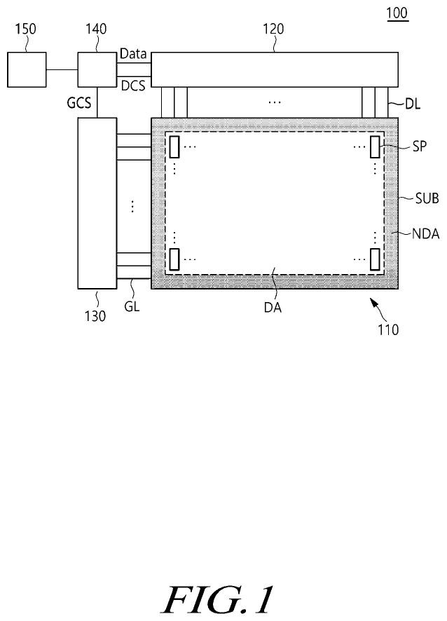

FIG. 1 is a view illustrating a system configuration of a display device 100 according to embodiments of the disclosure.

Referring to FIG. 1, a display device 100 according to embodiments of the disclosure may include a display panel 110 including a plurality of subpixels SP and driving circuits for driving the plurality of subpixels SP included in the display panel 110.

The driving circuits may include a data driving circuit 120 and a gate driving circuit 130. The display device 100 may further include a controller 140 controlling the data driving circuit 120 and the gate driving circuit 130.

The display panel 110 may include a substrate SUB and signal lines, such as a plurality of data lines DL and a plurality of gate lines GL disposed on the substrate SUB. The plurality of data lines DL and the plurality of gate lines GL may be connected to the plurality of subpixels SP.

The display panel 110 may include a display area DA in which images are displayed and a non-display area NDA in which no image is displayed. In the display panel 110, a plurality of subpixels SP for displaying images may be disposed in the display area DA, and the data driving circuit 120, the gate driving circuit 130, and the controllerl40 may be electrically connected or disposed in the non-display area NDA. Further, pad units for connection of integrated circuits or a printed circuit may be disposed in the non-display area NDA.

The data driving circuit 120 is a circuit for driving the plurality of data lines DL, and may supply data signals to the plurality of data lines DL.

The gate driving circuit 130 is a circuit for driving the plurality of gate lines GL, and may supply gate signals to the plurality of gate lines GL.

The controller 140 may supply a data control signal DCS to the data driving circuit 120 to control the operation timing of the data driving circuit 120 and may supply a gate control signal GCS to the gate driving circuit 130 to control the operation timing of the gate driving circuit 130.

The controller 140 may start scanning according to a timing implemented in each frame, convert input image data input from the outside into image data Data suited for the data signal format used in the data driving circuit 120, supply the image data Data to the data driving circuit 120, and control data driving at an appropriate time suited for scanning.

The controller 140 receives, from the outside (e.g., a host system 150), various timing signals including a vertical synchronization signal VSYNC, a horizontal synchronization signal HSYNC, an input data enable signal DE, and a clock signal, along with the input image data.

To control the data driving circuit 120 and the gate driving circuit 130, the controller 140 receives timing signals, such as the vertical synchronization signal VSYNC, horizontal synchronization signal HSYNC, input data enable signal DE, and clock signal CLK, generates various control signals DCS and GCS, and outputs the control signals to the data driving circuit 120 and the gate driving circuit 130.

As an example, to control the gate driving circuit 130, the controller 140 outputs various gate control signals GCS including a gate start pulse GSP, a gate shift clock GSC, and a gate output enable signal (Gate Output Enable, GOE).

To control the data driving circuit 120, the controller 140 outputs various data control signals DCS including, e.g., a source start pulse SSP, a source sampling clock SSC, and a source output enable signal (Source Output Enable, SOE).

The controller 140 may be implemented as a separate component from the data driving circuit 120, or the controller 140, along with the data driving circuit 120, may be implemented as an integrated circuit.

The data driving circuit 120 receives the image data Data from the controller 140 and supply data voltages to the plurality of data lines DL, thereby driving the plurality of data lines DL. The data driving circuit 120 is also referred to as a ‘source driving circuit.’

The data driving circuit 120 may include one or more source driver integrated circuit SDIC.

Each source driver integrated circuit (SDIC) may include a shift register, a latch circuit, a digital-to-analog converter (DAC), and an output buffer. In some cases, each source driver integrated circuit (SDIC) may further include an analog-digital converter ADC.

For example, each source driver integrated circuit (SDIC) may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may output a gate signal of a turn-on level voltage or a gate signal of a turn-off level voltage according to the control of the controller 140. The gate driving circuit 130 may sequentially drive the plurality of gate lines GL by sequentially supplying gate signals of the turn-on level voltage to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate in panel (GIP) type, in the non-display area NDA of the display panel 110. The gate driving circuit 130 may be disposed on the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type may be connected to the substrate SUB.

Meanwhile, at least one of the data driving circuit 120 and the gate driving circuit 130 may be disposed in the display area DA. For example, at least one of the data driving circuit 120 and the gate driving circuit 130 may be disposed not to overlap the subpixels SP or to overlap all or some of the subpixels SP.

When a selected gate line GL is driven by the gate driving circuit 130, the data driving circuit 120 may convert the image data Data received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the gate driving scheme and the panel design scheme, gate driving circuits 130 may be connected with both the sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point to point interface (EPI), and a serial peripheral interface (SPI).

The controller 140 may include a storage medium, such as one or more registers.

The display device 100 according to the present embodiments may be a display including a backlight unit, such as a liquid crystal display, or may be a self-emission display, such as an organic light emitting display device, a quantum dot display device, or an inorganic light emitting display device.

When the display device 100 according to the present embodiments is an organic light emitting display device, each subpixel SP may include an organic light emitting diode (OLED), which is self-emissive, as the light emitting element.

If the display device 100 according to the present embodiments is a quantum dot display device, each subpixel SP may include a light emitting element formed of a quantum dot, which is a self-emission semiconductor crystal.

If the display device 100 according to the present embodiments is an inorganic light emitting display device, each subpixel SP may include an inorganic light emitting element, which is self-emissive and formed of an inorganic material, as the light emitting element. For example, the inorganic light emitting element is also called a micro light emitting diode (micro-LED), and the inorganic light emitting display device is also called a micro-LED display device.

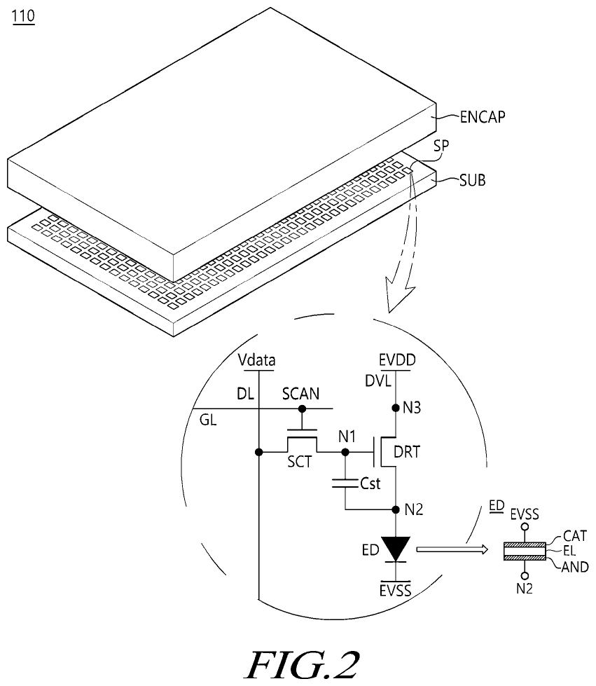

FIG. 2 is an equivalent circuit diagram illustrating a subpixel in a display panel 110 according to embodiments of the disclosure.

Referring to FIG. 2, each subpixel SP in the display area DA of the display panel 110 may include a light emitting element ED, a driving transistor DRT for driving the light emitting element ED, a scan transistor SCT for transferring a data voltage Vdata to a first node N1 of the driving transistor DRT, and a storage capacitor Cst for maintaining a constant voltage during one frame.

The driving transistor DRT may include the first node N1 to which the data voltage may be applied, a second node N2 electrically connected with the light emitting element ED, and a third node N3 to which a pixel driving voltage EVDD is applied from a driving voltage line DVL. The first node N1 in the driving transistor DRT may be a gate node, the second node N2 may be a source node or a drain node, and the third node N3 may be the drain node or the source node.

The light emitting element ED may include an anode electrode AND, a light emitting layer EL, and a cathode electrode CAT. The anode electrode AND may be a pixel electrode disposed in each subpixel SP and be electrically connected to the second node N2 of the driving transistor DRT of each subpixel SP. The cathode electrode CAT may be a common electrode commonly disposed in the plurality of subpixels SP, and a base voltage EVSS may be applied thereto.

For example, the anode electrode AND may be a pixel electrode, and the cathode electrode CAT may be a common electrode. Conversely, the anode electrode AND may be a common electrode, and the cathode electrode CAT may be a pixel electrode. Hereinafter, for convenience of description, it is assumed that the anode electrode AND is a pixel electrode and the cathode electrode CAT is a common electrode.

For example, the light emitting element ED may be an organic light emitting diode (OLED), an inorganic light emitting diode, or a quantum dot light emitting element. In this case, when the light emitting element ED is an organic light emitting diode, the light emitting layer EL of the light emitting element ED may include an organic light emitting layer including an organic material.

The scan transistor SCT may be on/off controlled by a scan signal SCAN, which is a gate signal, applied via the gate line GL and be electrically connected between the first node N1 of the driving transistor DRT and the data line DL.

The storage capacitor Cst may be electrically connected between the first node N1 and second node N2 of the driving transistor DRT.

Each subpixel SP may have a 2T (transistor)1C (capacitor) structure which includes two transistors DRT and SCT and one capacitor Cst as shown in FIG. 2 and, in some cases, each subpixel SP may further include one or more transistors or one or more capacitors.

The capacitor Cst may be an external capacitor intentionally designed to be outside the driving transistor DRT, but not a parasite capacitor (e.g., Cgs or Cgd) which is an internal capacitor that may be present between the first node N1 and the second node N2 of the driving transistor DRT.

Each of the driving transistor DRT and the scan transistor SCT may be an n-type transistor or a p-type transistor.

Since the circuit elements (particularly, the light emitting element ED) in each subpixel SP are vulnerable to external moisture or oxygen, an encapsulation layer ENCAP may be disposed on the display panel 110 to prevent penetration of external moisture or oxygen into the circuit elements (particularly, the light emitting element ED). The encapsulation layer ENCAP may be disposed to cover the light emitting elements ED.

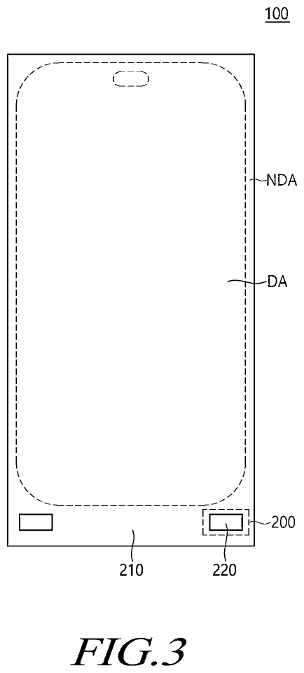

FIG. 3 is a view illustrating a system configuration of a display device 100 according to embodiments of the disclosure. What is identical or similar to those described in connection with FIGS. 1 and 2 may be omitted or briefly described below.

Referring to FIG. 3, the display device 100 according to embodiments of the disclosure may include a normal area 210 in which an electrostatic discharge element is not disposed and an electrostatic discharge area 220 in which an electrostatic discharge element is disposed.

The normal area 210 is an area surrounding the electrostatic discharge area 220 and may be an area including a display area DA and a non-display area NDA.

Referring to FIG. 3, the electrostatic discharge area 220 may be disposed in the non-display area NDA that is a corner portion of the display device 100, but is not limited thereto. For example, the electrostatic discharge area 220 may be disposed in at least one area of the non-display area NDA of the upper, lower, or side portion of the display device 100. Further, the electrostatic discharge area 220 may be disposed in the display area DA of the display device 100.

Meanwhile, the display device may be equipped with an input device using a touch sensor or the like, and an optical device such as a camera/proximity sensor or the like to provide the user with more various application functions. In particular, since the camera, the proximity sensor, and the like are inevitably exposed to the outside for light to enter and exit, the display area of the display panel may be reduced or the display device may be difficult to design.

In the display device 100 according to embodiments of the disclosure, a technology for hiding the camera, the proximity sensor, or the like under the display panel without being exposed to the outside is applied. Accordingly, since it is not necessary to form a separate area for exposure of the camera, the proximity sensor, or the like, the area of the display area DA may not be reduced, the size of the bezel area may be reduced, and design restrictions may be eliminated, thereby increasing the degree of freedom of design.

When an optical device such as a camera or a proximity sensor is disposed to be hidden under the display panel, a planarization layer disposed on the optical device may have a light transmittance of a predetermined level or more. However, when a planarization layer having a multilayer structure is fully applied to the display panel to secure a light transmittance of a predetermined level or more, pixel shrinkage may occur due to penetration of ultraviolet rays or external moisture and oxygen. Further, electrolytic corrosion may occur in the area in which the electrostatic discharge element is disposed.

Referring to FIG. 3, the electrostatic discharge area 220 may be distinguished from the normal area 210. In the display device 100 according to embodiments of the disclosure, a trench structure may be applied to a boundary between the electrostatic discharge area 220 and the normal area 210 to block penetration of external moisture and oxygen, thereby preventing pixel shrinkage and electrolytic corrosion. Further, penetration of external moisture and oxygen may be blocked by applying different structures to the planarization layer disposed in the electrostatic discharge area 220 and the planarization layer disposed in the normal area 210, thereby preventing pixel shrinkage and electrolytic corrosion.

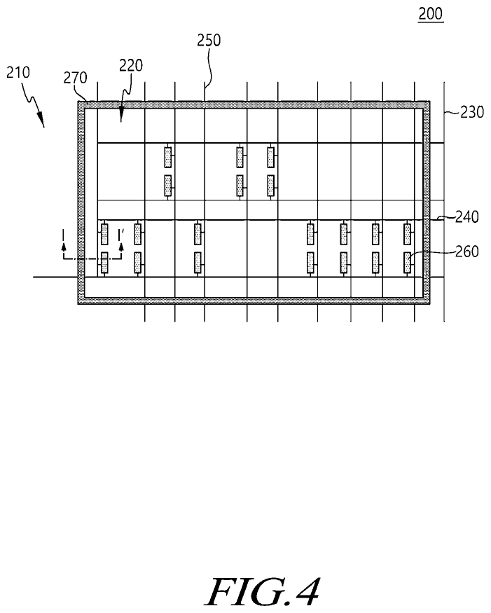

FIG. 4 is an enlarged plan view illustrating the area 200 of FIG. 3 according to one embodiment. What is identical or similar to those described with reference to FIGS. 1 to 3 is omitted from the following description or briefly described below.

Referring to FIG. 4, an area 200 may include a normal area 210, an electrostatic discharge area 220, and a trench 270.

The normal area 210 is an area in which the electrostatic discharge element 260 is not disposed, and may be disposed to surround the electrostatic discharge area 220.

The electrostatic discharge area 220 is an area including the electrostatic discharge element 260 and may include at least one electrostatic discharge element 260.

A trench 270 may be disposed between the normal area 210 and the electrostatic discharge area 220. The trench 270 may be disposed along a boundary separating the normal area 210 and the electrostatic discharge area 220.

Referring to FIG. 4, the trench 270 may be disposed to surround the electrostatic discharge area 220. The trench 270 may be disposed to surround the electrostatic discharge area 220 to prevent or delay penetration of external moisture and oxygen into the electrostatic discharge area 220 by the trench 270. Therefore, by applying the trench 270 structure, penetration of external moisture and oxygen may be blocked, thereby preventing pixel shrinkage and electrolytic corrosion.

Referring to FIG. 4, in the area 200, a plurality of gate lines 240 electrically connected to the gate driving circuit may be extended and disposed, and a plurality of data lines 250 electrically connected to the data driving circuit may be disposed to cross the gate lines 240.

Referring to FIG. 4, the electrostatic discharge area 220 may include at least one electrostatic discharge element 260.

One end of the electrostatic discharge element 260 may be electrically connected to the gate line 240 or the data line 250, but is not limited thereto. For example, the electrostatic discharge element 260 may be electrically connected to each of all lines including a common voltage line, a reference voltage line, and a power line. The other end of the electrostatic discharge element 260 may be electrically connected to the electrostatic discharge line 230. The electrostatic discharge line 230 may be electrically connected to a ground line or a base voltage line.

The electrostatic discharge element 260 may include at least one of a diode, a transistor, a capacitor, or an inductor. For example, the electrostatic discharge element 260 may be composed of one transistor or a plurality of transistors, or may be composed of a combination of a transistor and a capacitor.

When static electricity is introduced into the line connected to the electrostatic discharge element 260, the electrostatic discharge element 260 may be turned on, to discharge the static electricity to the electrostatic discharge line 230 to block static electricity.

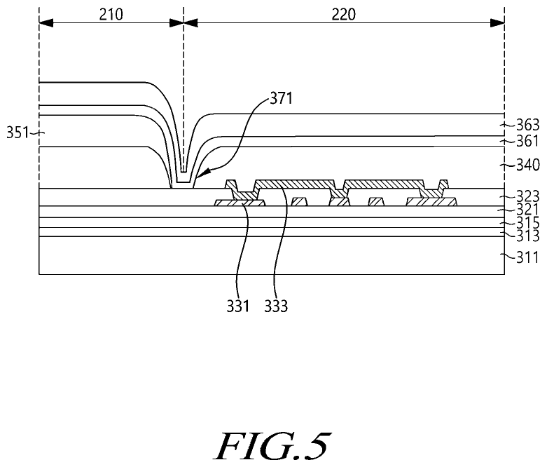

FIG. 5 is a cross-sectional view taken along line I-I′ of FIG. 4 according to one embodiment. What is identical or similar to those described in connection with FIGS. 1 to 4 may be omitted or briefly described below.

Referring to FIG. 5, a display device 100 according to embodiments of the disclosure may include a substrate 311, a lower planarization layer 340, a first trench 371, a first upper planarization layer 351, and an insulation layer 361.

The substrate 311 is a substrate for supporting various components of the display device 100. For example, the substrate 311 may be formed of glass, polyimide (PI), polyacrylate, polyacetate, or the like. The substrate 311 may be formed of a flexible material. The flexible may mean that the substrate 311 is foldable or bendable.

The substrate 311 may include a normal area 210 in which an electrostatic discharge element is not disposed and an electrostatic discharge area 220 in which an electrostatic discharge element is disposed. The normal area 210 may also be disposed to surround the electrostatic discharge area 220.

A multi-buffer layer 313 and an active buffer layer 315 may be disposed on the substrate 311. The multi-buffer layer 313 and the active buffer layer 315 may be collectively referred to as a buffer layer.

The multi-buffer layer 313 is a buffer layer in which a plurality of thin films are consecutively stacked, and for example, silicon nitride (SiNx) and silicon oxide (SiOx) may be alternately stacked. Alternatively, organic films and inorganic films may be repeatedly and alternately stacked. The multi-buffer layer 313 may serve to delay diffusion of moisture and/or oxygen penetrating the substrate 311.

The active buffer layer 315 may be disposed on the multi-buffer layer 313. The active buffer layer 315 is for protecting the active layer of the thin film transistor, and may perform a function of blocking various types of defects introduced from the substrate 311. The active buffer layer 315 may be formed of the same material as the multi-buffer layer 313, and may be formed of silicon oxide (SiOx) or amorphous silicon (a-Si).

An active layer (not shown) may be patterned and disposed on the active buffer layer 315.

A gate insulation layer 321 may be disposed on the active buffer layer 315 and the active layer (not shown). Agate electrode 331 may be disposed by depositing and patterning a gate metal on the gate insulation layer 321.

The gate insulation layer 321 may be composed of a single layer of silicon nitride (SiNx) or silicon oxide (SiOx), or may be composed of multiple layers of silicon nitride (SiNx) and silicon oxide (SiOx).

The gate electrode 331 may be formed of any one of aluminum (Al), an aluminum alloy (AlNd), copper (Cu), a copper alloy, molybdenum (Mo), and molytitanium (MoTi) having low resistance characteristics and may have a single layer structure, or may be formed of two or more thereof to have a double layer structure or a triple layer structure.

An interlayer insulation layer 323 may be disposed on the gate insulation layer 321 and the gate electrode 331.

The interlayer insulation layer 323 may be composed of a single layer of silicon nitride (SiNx) or silicon oxide (SiOx), or may be composed of multiple layers of silicon nitride (SiNx) and silicon oxide (SiOx).

A source/drain electrode 333 may be disposed by patterning a source/drain metal on the interlayer insulation layer 323.

Referring to FIG. 5, a lower planarization layer 340 may be disposed on the interlayer insulation layer 323 and the source/drain electrode 333.

The lower planarization layer 340 may function to planarize the upper portion of the interlayer insulation layer 323 on which the source/drain electrode 333 is disposed. The lower planarization layer 340 may be formed of an organic material. For example, it may be formed of an organic material such as an acryl resin, an epoxy resin, a phenolic resin, a polyamides resin, a polyimides resin, or the like, but is not limited thereto.

Referring to FIG. 5, a first trench 371 may be disposed in the lower planarization layer 340. The first trench 371 may be positioned between the normal area 210 and the electrostatic discharge area 220.

The first trench 371 may be formed by forming the lower planarization layer 340 and then etching a boundary portion between the normal area 210 and the electrostatic discharge area 220. Further, the first trench 371 may be provided by forming a lower planarization layer 340 after masking a boundary portion between the normal area 210 and the electrostatic discharge area 220.

Referring to FIG. 5, a first upper planarization layer 351 may be disposed on the lower planarization layer 340.

The first upper planarization layer 351 may be disposed in the normal area 210 in the lower planarization layer 340. For example, the first upper planarization layer 351 may be disposed on the lower planarization layer 340 in the normal area 210, but may not be disposed on the lower planarization layer 340 in the electrostatic discharge area 220.

The first upper planarization layer 351 may be formed of an organic material, but may be formed of an organic material different in kind from the organic material constituting the lower planarization layer 340. For example, the first upper planarization layer 351 may be formed of an organic material different from the lower planarization layer 340 among organic materials such as an acryl resin, an epoxy resin, a phenolic resin, a polyamides resin, and a polyimides resin, but is not limited thereto.

For example, the lower planarization layer 340 may be a polyimide resin, and the first upper planarization layer 351 may be a photo-acrylic resin.

Referring to FIG. 5, an insulation layer 361 may be disposed on the first upper planarization layer 351 and the lower planarization layer 340. The insulation layer 361 may be formed on the front surface of the substrate 311 including a boundary between the normal area 210 and the electrostatic discharge area 220, the normal area 210 and the electrostatic discharge area 220. For example, the insulation layer 361 may be continuously formed and disposed without being disconnected at the first trench 371.

An upper portion of the substrate 311 exposed through the first trench 371 may be covered by an insulation layer 361. For example, the interlayer insulation layer 323 exposed through the first trench 371 may be covered by the insulation layer 361.

The insulation layer 361 may be formed of an inorganic material. For example, the insulation layer 361 may be composed of a single layer of silicon nitride (SiNx) or silicon oxide (SiOx), or may be composed of multiple layers of silicon nitride (SiNx) and silicon oxide (SiOx).

The insulation layer 361 may be an inorganic layer or a touch inorganic layer of an encapsulation layer.

Referring to FIG. 5, a protective layer 363 may be disposed on the insulation layer 361. The protective layer 363 may be formed on the front surface of the insulation layer 361.

The protective layer 363 may be formed of an organic material. For example, the protective layer 363 may be a photo-acrylic resin.

The protective layer 363 may be an organic layer or a touch organic layer of the encapsulation layer.

Referring to FIG. 5, in the display device 100 according to embodiments of the disclosure, the first trench 371 may be applied to the lower planarization layer 340 at the boundary between the normal area 210 and the electrostatic discharge area 220, the first upper planarization layer 351 may be disposed in the normal area 210, and the insulation layer 361 formed of an inorganic material may be disposed on the front surface including the first trench 371 to block penetration of external moisture and oxygen, thereby preventing pixel shrinkage and electrolytic corrosion.

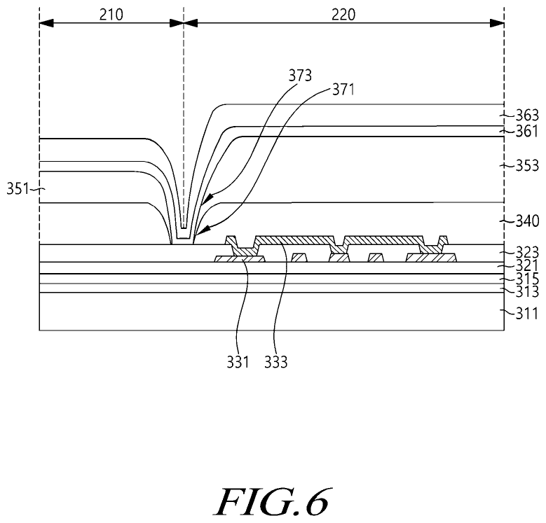

FIG. 6 is another cross-sectional view taken along line I-I′ of FIG. 4 according to one embodiment. What is identical or similar to those described in connection with FIGS. 1 to 5 may be omitted or briefly described below.

Referring to FIG. 6, a display device 100 according to embodiments of the disclosure may include a substrate 311, a lower planarization layer 340, a first trench 371, a first upper planarization layer 351, a second upper planarization layer 353, a second trench 373, and an insulation layer 361.

Referring to FIG. 6, the substrate 311, the lower planarization layer 340, the first trench 371, and the first upper planarization layer 351 are the same as or similar to the components illustrated in FIG. 5, and thus a detailed description thereof will be omitted.

Referring to FIG. 6, a multi-buffer layer 313 and an active buffer layer 315 may be disposed on a substrate 311.

An active layer (not shown) may be patterned and disposed on the active buffer layer 315.

A gate insulation layer 321 may be disposed on the active buffer layer 315 and the active layer (not shown).

Agate electrode 331 may be disposed by depositing and patterning a gate metal on the gate insulation layer 321.

An interlayer insulation layer 323 may be disposed on the gate insulation layer 321 and the gate electrode 331.

A source/drain electrode 333 may be disposed by patterning a source/drain metal on the interlayer insulation layer 323.

A lower planarization layer 340 may be disposed on the interlayer insulation layer 323 and the source/drain electrode 333.

A first trench 371 may be disposed in the lower planarization layer 340.

The first upper planarization layer 351 may be disposed in the normal area 210 on the lower planarization layer 340.

Referring to FIG. 6, a second upper planarization layer 353 may be disposed on the lower planarization layer 340.

The second upper planarization layer 353 may be disposed in the electrostatic discharge area 220 in the lower planarization layer 340. For example, the second upper planarization layer 353 may be disposed on the lower planarization layer 340 in the electrostatic discharge area 220, but may not be disposed on the lower planarization layer 340 in the normal area 210.

In other words, the first upper planarization layer 351 may be disposed on the lower planarization layer 340 in the normal area 210, the second upper planarization layer 353 may be disposed on the lower planarization layer 340 in the electrostatic discharge area 220, and the first and second trenches 371 and 373 may be disposed between the first upper planarization layer 351 and the second upper planarization layer 353.

The second upper planarization layer 353 may be formed of an organic material, but may be formed of an organic material different in kind from the organic material constituting the first upper planarization layer 351. For example, the second upper planarization layer 353 may be formed of an organic material different from the first upper planarization layer 351 among organic materials such as an acryl resin, an epoxy resin, a phenolic resin, a polyamides resin, and a polyimides resin, but is not limited thereto. Further, the second upper planarization layer 353 may be formed of the same kind of organic material as the organic material constituting the lower planarization layer 340.

For example, the first upper planarization layer 351 may be a photo-acrylic resin, and the second upper planarization layer 353 may be a polyimide resin. Further, the second upper planarization layer 353 and the lower planarization layer 340 may be the same polyimide resin.

Referring to FIG. 6, the second trench 373 may be positioned to overlap the first trench 371 and be disposed between the first upper planarization layer 351 and the second upper planarization layer 353.

The second trench 373 may be positioned between the normal area 210 and the electrostatic discharge area 220.

The second trench 373 may be provided by forming the first trench 371, masking a boundary portion between the normal area 210 and the electrostatic discharge area 220, and then forming the first upper planarization layer 351 and the second upper planarization layer 353.

Referring to FIG. 6, an insulation layer 361 may be disposed on the first upper planarization layer 351 and the second upper planarization layer 353. The insulation layer 361 may be formed on the front surface of the substrate 311 including a boundary between the normal area 210 and the electrostatic discharge area 220, the normal area 210 and the electrostatic discharge area 220. For example, the insulation layer 361 may be continuously formed and disposed without being disconnected at the first trench 371 and the second trench 373.

An upper portion of the substrate 311 exposed through the first trench 371 and the second trench 373 may be covered by the insulation layer 361. For example, the interlayer insulation layer 323 exposed through the first trench 371 and the second trench 373 may be covered by the insulation layer 361.

A protective layer 363 may be disposed on the insulation layer 361.

Referring to FIG. 6, in the display device 100 according to embodiments of the disclosure, the first trench 371 may be applied to the lower planarization layer 340 at the boundary between the normal area 210 and the electrostatic discharge area 220, the first upper planarization layer 351 may be disposed in the normal area 210, the second upper planarization layer 353 may be disposed in the electrostatic discharge area 220, and the insulation layer 361 formed of an inorganic material may be disposed on the front surface including the first trench 371 and the second trench 373 to block penetration of external moisture and oxygen, thereby preventing pixel shrinkage and electrolytic corrosion.

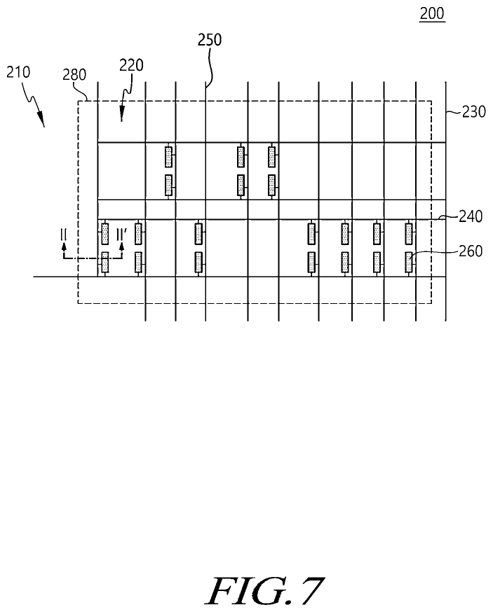

FIG. 7 is another enlarged plan view illustrating the area 200 of FIG. 3 according to one embodiment. What is identical or similar to those described with reference to FIGS. 1 to 6 is omitted from the following description or briefly described below.

Referring to FIG. 7, an area 200 may include a normal area 210, an electrostatic discharge area 220, an electrostatic discharge line 230, a gate line 240, a data line 250, and an electrostatic discharge element 260, and may include a boundary 280 separating the normal area 210 and the electrostatic discharge area 220.

Referring to FIG. 7, the normal area 210, the electrostatic discharge area 220, the electrostatic discharge line 230, the gate line 240, the data line 250, and the electrostatic discharge element 260 are the same as or similar to the components illustrated in FIG. 4, and thus a detailed description thereof will be omitted.

Referring to FIG. 7, a boundary 280 may be disposed to separate the normal area 210 in which the electrostatic discharge element 260 is not disposed from the electrostatic discharge area 220 in which the electrostatic discharge element 260 is disposed.

The normal area 210 may be disposed to surround the electrostatic discharge area 220 along the boundary 280.

A plurality of gate lines 240 and a plurality of data lines 250 crossing the plurality of gate lines 240 may be disposed.

The electrostatic discharge area 220 may include at least one electrostatic discharge element 260.

An electrostatic discharge line 230 electrically connected to the other end of the electrostatic discharge element 260 may be disposed.

Referring to FIG. 7, the electrostatic discharge area 220 may be distinguished from the normal area 210. In the display device 100 according to embodiments of the disclosure, the structure of the planarization layer disposed in the electrostatic discharge area 220 may be applied differently from the structure of the planarization layer disposed in the normal area 210 to block penetration of external moisture and oxygen, thereby preventing pixel shrinkage and electrolytic corrosion.

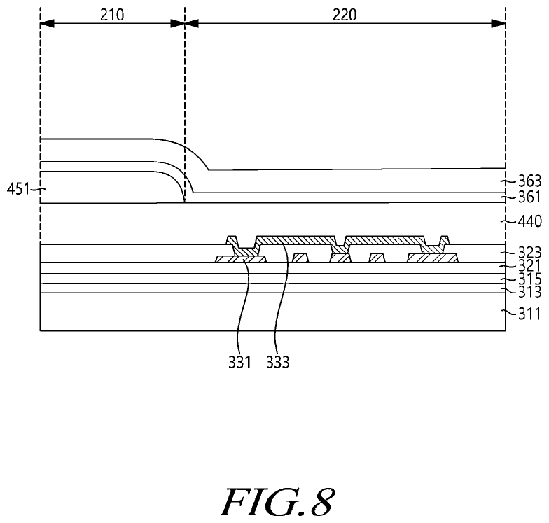

FIG. 8 is a cross-sectional view taken along line II-II′ of FIG. 7 according to one embodiment. What is identical or similar to those described with reference to FIGS. 1 to 7 is omitted from the following description or briefly described below.

Referring to FIG. 8, a display device 100 according to embodiments of the disclosure may include a substrate 311, a lower planarization layer 440, a first upper planarization layer 451, and an insulation layer 361.

Referring to FIG. 8, the configuration of the substrate 311 is the same as or similar to the configuration illustrated in FIG. 5, and thus a detailed description thereof will be omitted.

Referring to FIG. 8, a multi-buffer layer 313 and an active buffer layer 315 may be disposed on a substrate 311.

An active layer (not shown) may be patterned and disposed on the active buffer layer 315.

A gate insulation layer 321 may be disposed on the active buffer layer 315 and the active layer (not shown).

Agate electrode 331 may be disposed by depositing and patterning a gate metal on the gate insulation layer 321.

An interlayer insulation layer 323 may be disposed on the gate insulation layer 321 and the gate electrode 331.

A source/drain electrode 333 may be disposed by patterning a source/drain metal on the interlayer insulation layer 323.

Referring to FIG. 8, a lower planarization layer 440 may be disposed on the interlayer insulation layer 323 and the source/drain electrode 333.

The lower planarization layer 440 may function to planarize the upper portion of the interlayer insulation layer 323 on which the source/drain electrode 333 is disposed. The lower planarization layer 440 may be formed of an organic material. For example, it may be formed of an organic material such as an acryl resin, an epoxy resin, a phenolic resin, a polyamides resin, a polyimides resin, or the like, but is not limited thereto.

The lower planarization layer 440 may be formed on the front surface of the substrate 331.

Referring to FIG. 8, a first upper planarization layer 451 may be disposed on the lower planarization layer 440.

The first upper planarization layer 451 may be disposed in the normal area 210 in the lower planarization layer 440. For example, the first upper planarization layer 451 may be disposed on the lower planarization layer 440 in the normal area 210, but may not be disposed on the lower planarization layer 440 in the electrostatic discharge area 220.

The first upper planarization layer 451 may be formed of an organic material, but may be formed of an organic material different in kind from the organic material constituting the lower planarization layer 440. For example, the first upper planarization layer 451 may be formed of an organic material different from the lower planarization layer 440 among organic materials such as an acryl resin, an epoxy resin, a phenolic resin, a polyamides resin, and a polyimides resin, but is not limited thereto.

For example, the lower planarization layer 440 may be a polyimide resin, and the first upper planarization layer 451 may be a photo-acrylic resin.

Referring to FIG. 8, an insulation layer 361 may be disposed on the first upper planarization layer 451 and the lower planarization layer 440. The insulation layer 361 may include the normal area 210 and the electrostatic discharge area 220 and may be formed on the front surface of the substrate 311.

The insulation layer 361 may be formed of an inorganic material. For example, the insulation layer 361 may be composed of a single layer of silicon nitride (SiNx) or silicon oxide (SiOx), or may be composed of multiple layers of silicon nitride (SiNx) and silicon oxide (SiOx).

The insulation layer 361 may be an inorganic layer or a touch inorganic layer of an encapsulation layer.

Referring to FIG. 8, a protective layer 363 may be disposed on the insulation layer 361. The protective layer 363 may be formed on the front surface of the insulation layer 461.

The protective layer 363 may be formed of an organic material. For example, the protective layer 363 may be a photo-acrylic resin.

The protective layer 363 may be an organic layer or a touch organic layer of the encapsulation layer.

Referring to FIG. 8, in the display device 100 according to embodiments of the disclosure, a first upper planarization layer 451 may be disposed in the normal area 210 of the lower planarization layer 440, and an insulation layer 361 formed of an inorganic material may be disposed on the front surface of the first upper planarization layer 451 and the lower planarization layer 440 to block penetration of external moisture and oxygen, thereby preventing pixel shrinkage and electrolytic corrosion.

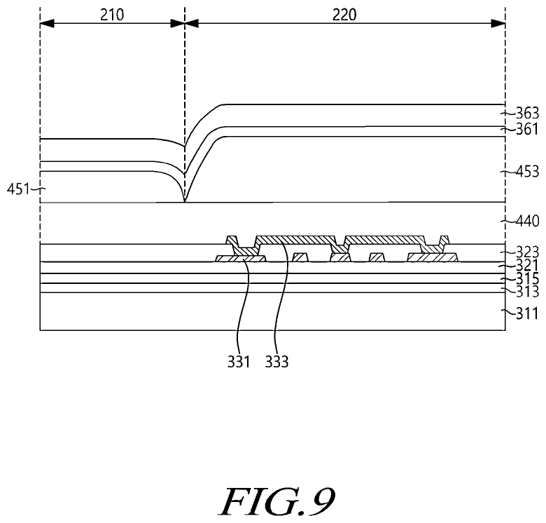

FIG. 9 is another cross-sectional view taken along line II-II′ of FIG. 7 according to one embodiment. What is identical or similar to those described with reference to FIGS. 1 to 8 is omitted from the following description or briefly described below.

Referring to FIG. 9, a display device 100 according to embodiments of the disclosure may include a substrate 311, a lower planarization layer 440, a first upper planarization layer 451, a second upper planarization layer 453, and an insulation layer 361.

Referring to FIG. 9, the substrate 311, the lower planarization layer 440, and the first upper planarization layer 451 are the same as or similar to the components illustrated in FIG. 8, and thus a detailed description thereof will be omitted.

Referring to FIG. 9, a multi-buffer layer 313 and an active buffer layer 315 may be disposed on the substrate 311.

An active layer (not shown) may be patterned and disposed on the active buffer layer 315.

A gate insulation layer 321 may be disposed on the active buffer layer 315 and the active layer (not shown).

Agate electrode 331 may be disposed by depositing and patterning a gate metal on the gate insulation layer 321.

An interlayer insulation layer 323 may be disposed on the gate insulation layer 321 and the gate electrode 331.

A source/drain electrode 333 may be disposed by patterning a source/drain metal on the interlayer insulation layer 323.

A lower planarization layer 440 may be disposed on the interlayer insulation layer 323 and the source/drain electrode 333.

The first upper planarization layer 451 may be disposed in the normal area 210 on the lower planarization layer 440.

Referring to FIG. 9, a second upper planarization layer 453 may be disposed on the lower planarization layer 440.

The second upper planarization layer 453 may be disposed in the electrostatic discharge area 220 in the lower planarization layer 440. For example, the second upper planarization layer 453 may be disposed on the lower planarization layer 440 in the electrostatic discharge area 220, but may not be disposed on the lower planarization layer 440 in the normal area 210.

In other words, the first upper planarization layer 451 may be disposed on the lower planarization layer 440 in the normal area 210, and the second upper planarization layer 453 may be disposed on the lower planarization layer 440 in the electrostatic discharge area 220. The first upper planarization layer 451 and the second upper planarization layer 453 may be disposed to be disconnected.

The second upper planarization layer 453 may be formed of an organic material, but may be formed of an organic material different in kind from the organic material constituting the first upper planarization layer 451. For example, the second upper planarization layer 453 may be formed of an organic material different from the first upper planarization layer 453 among organic materials such as an acryl resin, an epoxy resin, a phenolic resin, a polyamides resin, and a polyimides resin, but is not limited thereto. Further, the second upper planarization layer 453 may be formed of the same kind of organic material as the organic material constituting the lower planarization layer 440.

For example, the first upper planarization layer 451 may be a photo-acrylic resin, and the second upper planarization layer 453 may be a polyimide resin. Further, the second upper planarization layer 453 and the lower planarization layer 440 may be the same polyimide resin.

An insulation layer 361 may be disposed on the first upper planarization layer 451 and the second upper planarization layer 453.

A protective layer 363 may be disposed on the insulation layer 361.

Referring to FIG. 9, in the display device 100 according to embodiments of the disclosure, the first upper planarization layer 451 may be disposed in the normal area 210 of the lower planarization layer 440, the second upper planarization layer 451 may be disposed in the electrostatic discharge area 220 of the lower planarization layer 440, and the insulation layer 361 formed of an inorganic material may be disposed on the front surfaces of the first upper planarization layer 451 and the second upper planarization layer 451 to block penetration of external moisture and oxygen, thereby preventing pixel shrinkage and electrolytic corrosion.

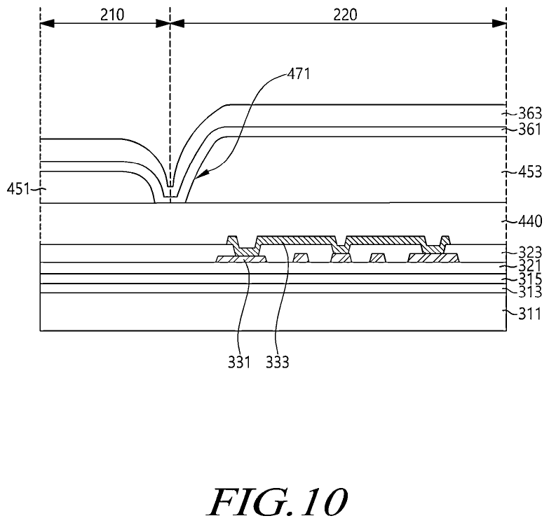

FIG. 10 is another cross-sectional view taken along line II-II′ of FIG. 7 according to one embodiment. What is identical or similar to those described in connection with FIGS. 1 to 9 may be omitted or briefly described below.

Referring to FIG. 10, a display device 100 according to embodiments of the disclosure may include a substrate 311, a lower planarization layer 440, a first upper planarization layer 451, a second upper planarization layer 453, a trench 471, and an insulation layer 361.

Referring to FIG. 10, the substrate 311, the lower planarization layer 440, the first upper planarization layer 451, the second upper planarization layer 453, and the insulation layer 361 are the same as or similar to the components illustrated in FIG. 9, and thus a detailed description thereof will be omitted.

Referring to FIG. 10, a multi-buffer layer 313 and an active buffer layer 315 may be disposed on a substrate 311.

An active layer (not shown) may be patterned and disposed on the active buffer layer 315.

A gate insulation layer 321 may be disposed on the active buffer layer 315 and the active layer (not shown).

Agate electrode 331 may be disposed by depositing and patterning a gate metal on the gate insulation layer 321.

An interlayer insulation layer 323 may be disposed on the gate insulation layer 321 and the gate electrode 331.

A source/drain electrode 333 may be disposed by patterning a source/drain metal on the interlayer insulation layer 323.

A lower planarization layer 440 may be disposed on the interlayer insulation layer 323 and the source/drain electrode 333.

The first upper planarization layer 451 may be disposed in the normal area 210 on the lower planarization layer 440.

A second upper planarization layer 453 may be disposed in the electrostatic discharge area 220 on the lower planarization layer 440.

Referring to FIG. 10, a trench 471 may be disposed between the first upper planarization layer 451 and the second upper planarization layer 453.

The trench 471 may be positioned between the normal area 210 and the electrostatic discharge area 220.

Referring to FIG. 10, an insulation layer 361 may be disposed on the first upper planarization layer 451 and the second upper planarization layer 453. The insulation layer 361 may be formed on the front surface of the lower planarization layer 440 including a boundary between the normal area 210 and the electrostatic discharge area 220, the normal area 210 and the electrostatic discharge area 220.

The lower planarization layer 440 exposed through the trench 471 may be covered by the insulation layer 361.

A protective layer 363 may be disposed on the insulation layer 361.

Referring to FIG. 10, in the display device 100 according to embodiments of the disclosure, the first upper planarization layer 451 may be disposed in the normal area 210 of the lower planarization layer 440, the second upper planarization layer 453 may be disposed in the electrostatic discharge area 220 of the lower planarization layer 440, and the insulation layer 361 formed of an inorganic material may be disposed on the front surface including the trench 471 between the first upper planarization layer 451 and the second upper planarization layer 453 to block penetration of external moisture and oxygen, thereby preventing or at least reducing pixel shrinkage and electrolytic corrosion.

Embodiments of the disclosure described above are briefly described below.

Embodiments of the disclosure provide a display device comprising a substrate including an electrostatic discharge area where an electrostatic discharge element is disposed and a normal area surrounding the electrostatic discharge area, a lower planarization layer disposed on the substrate, a first trench positioned between the electrostatic discharge area and the normal area, and disposed in the lower planarization layer, a first upper planarization layer positioned in the normal area, and disposed on the lower planarization layer, and an insulation layer disposed on the first upper planarization layer, the first trench, and the lower planarization layer, and formed of an inorganic material.

The display device according to embodiments of the disclosure may further comprise a second upper planarization layer positioned in the electrostatic discharge area, and disposed between the lower planarization layer and the insulation layer.

The display device according to embodiments of the disclosure may further comprise a second trench positioned to overlap the first trench, and disposed between the first upper planarization layer and the second upper planarization layer.

In the display device according to embodiments of the disclosure, the first trench and the second trench may surround the electrostatic discharge area, and the substrate exposed through the first trench and the second trench may be covered by the insulation layer.

In the display device according to embodiments of the disclosure, the lowerr planarization layer may be formed of an organic material, and the first upper planarization layer may be formed of an organic material different from the lower planarization layer.

In the display device according to embodiments of the disclosure, a gate line and a data line crossing the gate line may be disposed on the substrate, and an end of the electrostatic discharge element may be electrically connected to the gate line or the data line.

In the display device according to embodiments of the disclosure, another end of the electrostatic discharge element may be electrically connected to an electrostatic discharge line.

Embodiments of the disclosure may provide a display device comprising a substrate including an electrostatic discharge area where an electrostatic discharge element is disposed and a normal area where the electrostatic discharge element is not disposed, a lower planarization layer disposed in the normal area and the electrostatic discharge area, and including an organic material, a first upper planarization layer positioned in the normal area, and disposed on the lower planarization layer, and an insulation layer disposed on the first upper planarization layer and the lower planarization layer, and formed of an inorganic material.

The display device according to embodiments of the disclosure may further comprise a second upper planarization layer positioned in the electrostatic discharge area, and disposed between the lower planarization layer and the insulation layer.

The display device according to embodiments of the disclosure may further comprise a trench disposed between the first upper planarization layer and the second upper planarization layer.

In the display device according to embodiments of the disclosure, the trench may surround the electrostatic discharge area, and the lower planarization layer exposed through the trench may be covered by the insulation layer.

In the display device according to embodiments of the disclosure, the lower planarization layer may be formed of an organic material, and the first upper planarization layer may be formed of an organic material different from the lower planarization layer.

In the display device according to embodiments of the disclosure, the second upper planarization layer may be formed of an organic material different from the first upper planarization layer.

In the display device according to embodiments of the disclosure, a gate line and a data line crossing the gate line may be disposed on the substrate, and an end of the electrostatic discharge element may be electrically connected to the gate line or the data line.

In the display device according to embodiments of the disclosure, another end of the electrostatic discharge element may be electrically connected to an electrostatic discharge line.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a substrate including an electrostatic discharge area where an electrostatic discharge element is disposed and a normal area surrounding the electrostatic discharge area;
a lower planarization layer on the substrate;
a first trench between the electrostatic discharge area and the normal area, the first trench in the lower planarization layer;
a first upper planarization layer in the normal area and on the lower planarization layer; and
an insulation layer on the first upper planarization layer, the first trench, and the lower planarization layer, the insulation layer including an inorganic material.

2. The display device of claim 1, further comprising:
a second upper planarization layer in the electrostatic discharge area, the second upper planarization layer between the lower planarization layer and the insulation layer.

3. The display device of claim 2, further comprising:
a second trench that overlaps the first trench, the second trench between the first upper planarization layer and the second upper planarization layer.

4. The display device of claim 3, wherein the first trench and the second trench surround the electrostatic discharge area, and the substrate exposed through the first trench and the second trench is covered by the insulation layer.

5. The display device of claim 2, wherein the lower planarization layer includes an organic material, and the first upper planarization layer includes an organic material different from the lower planarization layer.

6. The display device of claim 1, further comprising:
a gate line and a data line crossing the gate line on the substrate, and
wherein an end of the electrostatic discharge element is electrically connected to the gate line or the data line.

7. The display device of claim 6, wherein another end of the electrostatic discharge element is electrically connected to an electrostatic discharge line.

8. A display device, comprising:
a substrate including an electrostatic discharge area where an electrostatic discharge element is disposed and a normal area where the electrostatic discharge element is not disposed;
a lower planarization layer in the normal area and the electrostatic discharge area, the lower planarization layer including an organic material;
a first upper planarization layer in the normal area, and on the lower planarization layer; and
an insulation layer on the first upper planarization layer and the lower planarization layer, the insulation layer including an inorganic material.

9. The display device of claim 8, further comprising:
a second upper planarization layer in the electrostatic discharge area, and between the lower planarization layer and the insulation layer.

10. The display device of claim 9, further comprising:
a trench between the first upper planarization layer and the second upper planarization layer.

11. The display device of claim 10, wherein the trench surrounds the electrostatic discharge area, and the lower planarization layer exposed through the trench is covered by the insulation layer.

12. The display device of claim 9, wherein the lower planarization layer includes an organic material, and the first upper planarization layer includes an organic material different from the lower planarization layer.

13. The display device of claim 12, wherein the second upper planarization layer includes an organic material different from the first upper planarization layer.

14. The display device of claim 8, further comprising:
a gate line and a data line crossing the gate line on the substrate,
wherein an end of the electrostatic discharge element is electrically connected to the gate line or the data line.

15. The display device of claim 14, wherein another end of the electrostatic discharge element is electrically connected to an electrostatic discharge line.
